(19) United States
(12) Patent Application Publication
(10) Pub. No.: US 2016/0020139 A1
(43) Pub. Date: Jan. 21, 2016

(54) GAP-FILLING DIELECTRIC LAYER METHOD FOR MANUFACTURING THE SAME AND APPLICATIONS THEREOF

(71) Applicant: United Microelectronics Corp., HSINCHU (TW)

(72) Inventors: Wen-Yi Teng, Kaohsiung City (TW); Yuh-Min Lin, Tainan City (TW); Chih-Chien Liu, Taipei City (TW); Chieh-Wen Lo, Tainan City (TW)

(21) Appl. No.: 14/478,609

(22) Filed: Sep. 5, 2014

(30) Foreign Application Priority Data
Jul. 18, 2014 (CN) 201410344914.X

(51) Int. Cl. H01L 21/762; H01L 23/58; H01L 21/02; H01L 29/06

(52) U.S. Cl. CPC H01L 21/76224; H01L 29/0649; H01L 23/58; H01L 21/02271; H01L 21/02211

(57) ABSTRACT

A gap-filling dielectric layer, method for fabricating the same and applications thereof are disclosed. A silicon-containing dielectric layer is firstly deposited on a substrate. The silicon-containing dielectric layer is then subjected to a curing process, an in-situ wetting treatment and an annealing process in sequence, whereby a gap-filling dielectric layer with a nitrogen atom density less than 1×10²² atoms/cm³ is formed.

This application claims the benefit of People's Republic of China application Serial No. 201410344914.X, filed Jul. 18, 2014, the subject matter of which is incorporated herein by reference.

### BACKGROUND

1. Technical Field

The disclosure relates in general to a dielectric layer utilized in a semiconductor device, method for manufacturing the same and the applications thereof, and more particularly to a gap-filling dielectric layer, method for fabricating the same and applications thereof are disclosed.

2. Description of the Related Art

In the course of semiconductor integrated circuit (IC) evolution, greater functional density and decreasing feature sizes are required, therefor the number of devices per chip area has generally increased while geometry size (i.e., the smallest component (or line) that can be created using a fabrication process) has decreased. The decreasing feature sizes result in structural features on the devices having decreased pitches (i.e., the spatial dimensions between two adjacent devices) and make the widths of gaps and trenches used for fabricating an isolation structures, such as a shallow trench isolation (STI), narrow to a point where the aspect ratio of gap depth to its width becomes high enough to make it challenging to fill the gap with dielectric material.

Thus, when a traditional gap-filling process is performed, the narrowed gaps and trenches could make the depositing dielectric material prone to clog at the top before the gap completely fills, producing a void or seam in the middle of the gap. For purpose to solve the problems of the void, a flowable chemical vapor deposition (FCVD) system has been introduced to form a gap-filling dielectric layer using silicon-and-nitrogen precursor with high flowability, such as, trisilane (TSA). However, the gap-filling dielectric layer formed by the FCVD system has soft texture due to its relatively high nitrogen content, thus a subsequent cure process is required to convert Si—N bonding configuration of the gap-filling dielectric layer into Si—O bonds in an oxygen containing atmosphere. A silicon oxide layer having relative compact texture is then formed by a subsequent thermal annealing process. But, the conversion efficiency of the curing process remains to be improved. It is difficult to make a gap-filling dielectric layer that fabricated by the FCVD system having a quality identical to a prior art gap-filling dielectric layer fabricated by the traditional gap-filling process with the same processing time and thermal budget that are rather limited.

Therefore, there is a need of providing an improved gap-filling dielectric layer and method for fabricating the same to obviate the drawbacks encountered from the prior art.

### SUMMARY

One aspect of the present invention is to provide a gap-filling dielectric layer with good gap-filling ability, wherein the gap-filling dielectric layer has a nitrogen atom density substantially less than 1×10²² atoms/cm³.

According to another aspect of the present invention, a method for fabricating a gap-filling dielectric layer is disclosed to provide a gap-filling dielectric layer having improved gap-filling ability and good dielectric properties with a limited processing time and thermal budget, wherein the method comprises steps as follows: A silicon-containing dielectric layer is firstly deposited on a substrate. The silicon-containing dielectric layer is then subjected to a curing process, an in-situ wetting treatment and an annealing process in sequence.

According to yet another aspect of the present invention, a semiconductor device having a gap-filling dielectric layer with improved gap-filling ability and good dielectric properties is provided, wherein the semiconductor device comprises a substrate and a gap-filling dielectric layer having a nitrogen atom density less than 1×10²² atoms/cm³ formed on the substrate.

According to yet another aspect of the present invention, a method for fabricating a semiconductor device having a gap-filling dielectric layer with improved gap-filling ability and good dielectric properties is provided, wherein the method comprises steps as follows: A substrate is firstly provided, and a silicon-containing dielectric layer is deposited on the substrate. The silicon-containing dielectric layer is then subjected to a curing process, an in-situ wetting treatment and an annealing process in sequence.

In accordance with the aforementioned embodiments of the present invention, a substrate is firstly provided, and a silicon-containing dielectric layer is deposited on the substrate. The silicon-containing dielectric layer is then subjected to a curing process, an in-situ wetting treatment and an annealing process in sequence, whereby a gap-filling dielectric layer having a nitrogen atom density less than 1×10²² atoms/cm³ is formed on the substrate with a limited processing time and thermal budget. Since the gap-filling dielectric layer has improved gap-filling ability and good dielectric properties, thus the problems encountered by the prior art gap-filling dielectric layer due to the shrink in feature sizes of semiconductor IC can be solved.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a is a block diagram illustrating a method for fabricating a semiconductor device having a gap-filling dielectric layer in accordance with one embodiment of the present invention;

FIGS. 2A-2F are cross-sectional views of the processing structures for fabricating a semiconductor device having a gap-filling dielectric layer in accordance with one embodiment of the present invention;

FIG. 3 is a top view of a processing apparatus for forming a semiconductor device in accordance with one embodiment of the present invention; and

FIG. 4 is a statistic chart illustrating the refractive index deviations of different gap-filling dielectric layers that are measured by an ellipsometer in accordance with one embodiment of the present invention.

### DETAILED DESCRIPTION

The embodiments as illustrated below provide a gap-filling dielectric layer with good gap-filling ability, method of manufacturing the same and applications thereof. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed. Also, it is also important to point out that there may be other features, elements, steps and parameters for implementing the embodiments of the present disclosure which are not specifically illustrated. Thus, the specification and the drawings are to be regard as an illustrative sense rather than a restrictive sense. Various modifications and similar arrangements may be provided by the persons skilled in the art within the spirit and scope of the present invention. In addition, the illustrations may not be necessarily be drawn to scale, and the identical elements of the embodiments are designated with the same reference numerals.

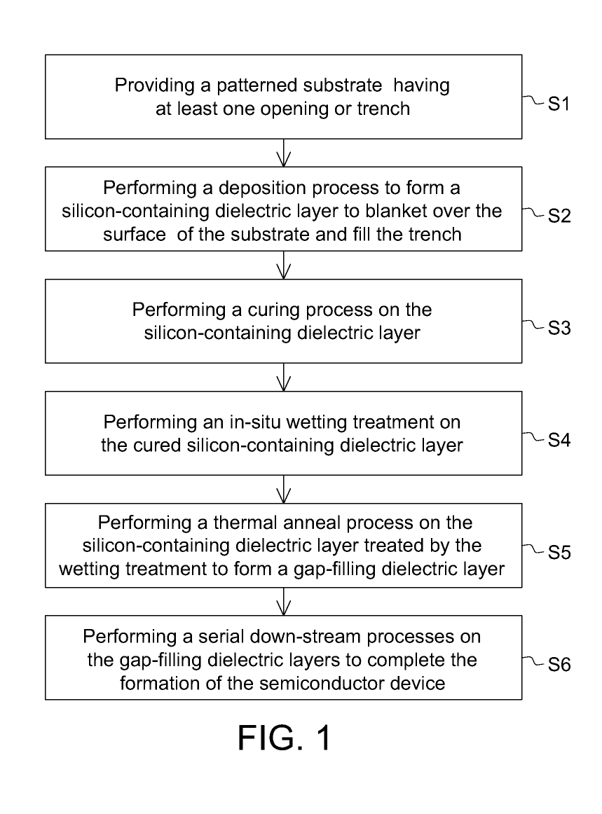

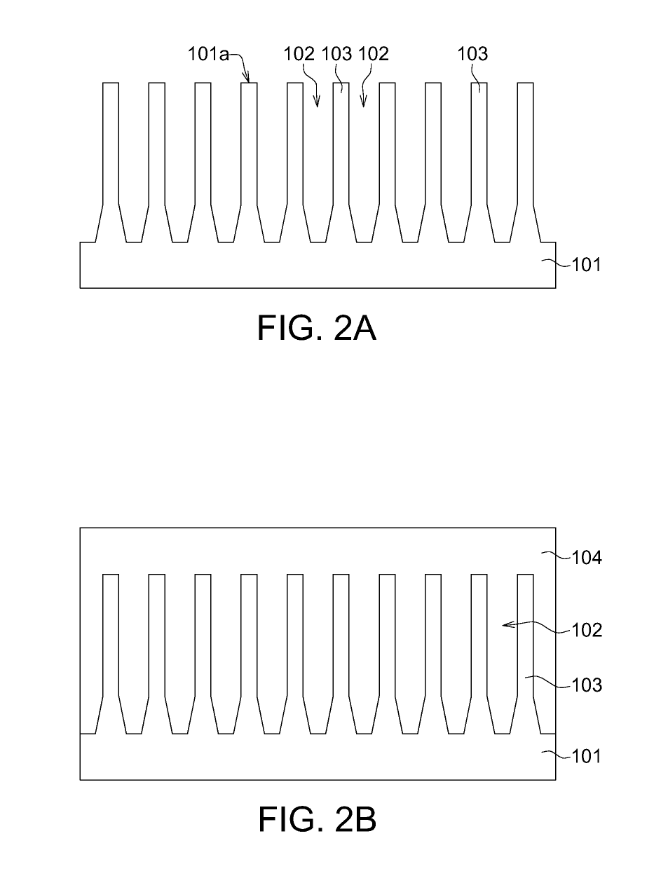

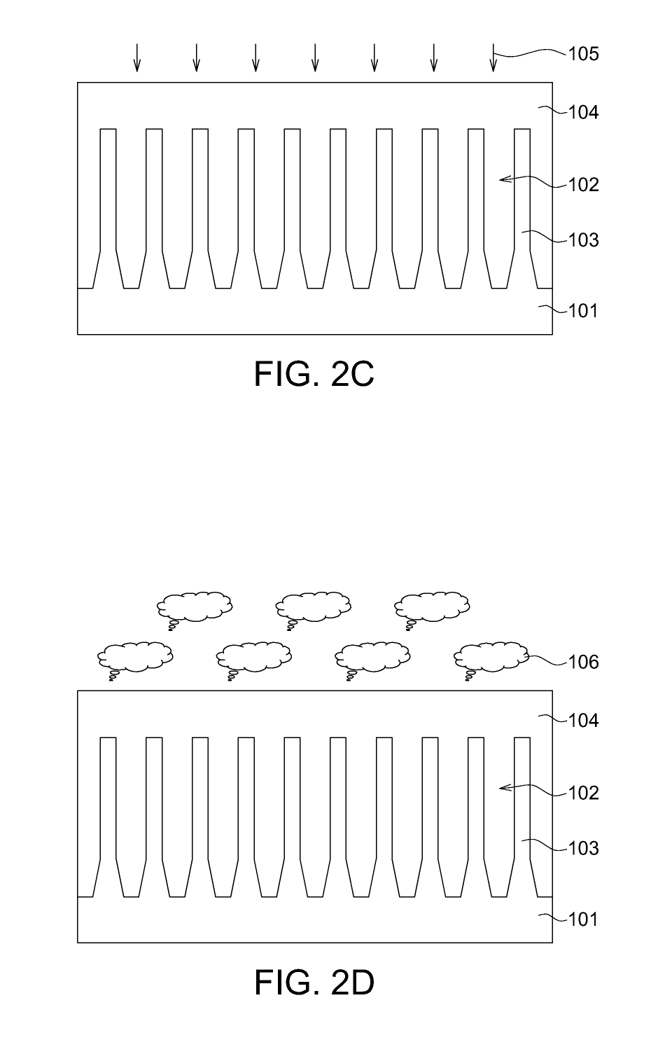

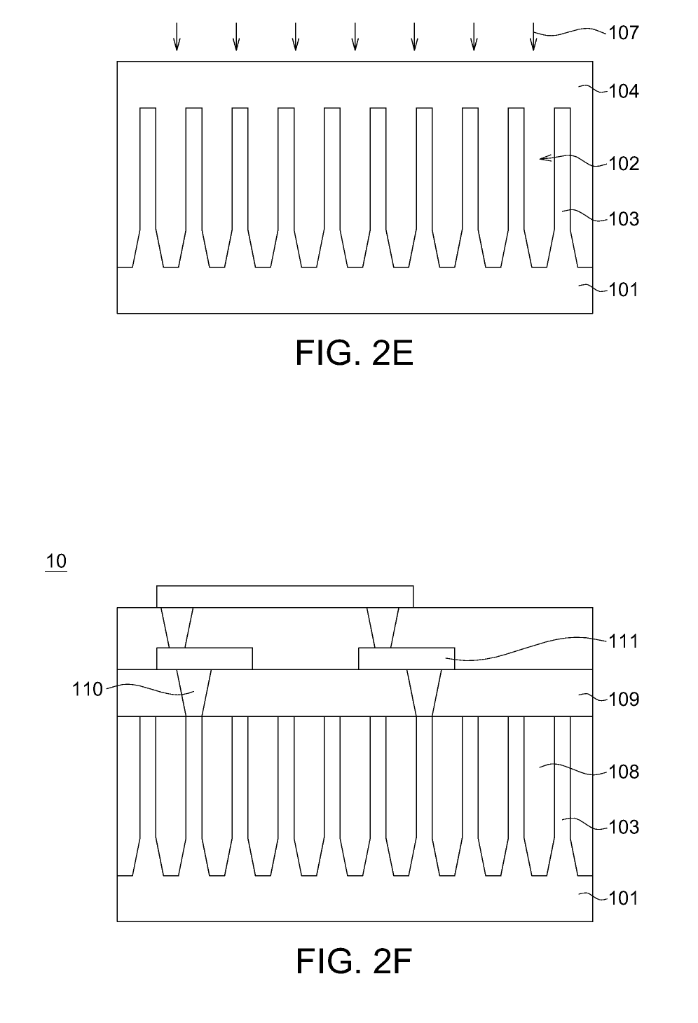

FIG. 1 is a is a block diagram illustrating a method for fabricating a semiconductor device 10 having a gap-filling dielectric layer 100 in accordance with one embodiment of the present invention. FIGS. 2A-2F are cross-sectional views of the processing structures for fabricating the semiconductor device 10 having the gap-filling dielectric layer 100. The method comprises several steps as follows:

Firstly, referring to the step S1 of FIG. 1, a patterned substrate 101 having at least one opening or trench 102 is provided. In some embodiments of the present invention, the substrate 101 may be a silicon substrate. In some other embodiments of the present invention, the substrate 101 not only comprises an intrinsic semiconductor layer but also comprises another semiconductor material layer, such as an epitaxial layer or an insulation layer formed thereon. For example, in some embodiments of the present embodiment, the substrate 101 can be a silicon on insulator (SOI) substrate that comprises an insulation layer. In the present embodiment, the substrate 101 can be a silicon wafer. In addition, there may be several semiconductor elements (not shown) formed on/in the substrate 101 by a front-end process.

The patterning of the substrate 101 is implemented by performing a dry or wet etching process on a surface 101a of the substrate 101, so as to remove a portion of the substrate 101 and form at least one trench 102 on the surface 101a. In the present embodiment, the substrate 101 is patterned by a dry etching process, such as a reactive ion etching (RIE) process, to form a plurality of trenches 102 on the surface 101a of the substrate 101 by which a plurality of fins 103 can be defined in the substrate 101 (as shown in FIG. 2A).

Next, referring to the step S2 of FIG. 1, a deposition process is performed, such as a chemical vapor deposition (CVD) process or a FCVD process, to form a silicon-containing dielectric layer 104 to blanket over the surface 101a of the substrate 101 and fill the trenches 102 (as shown in FIG. 2B). In some embodiments of the present invention, the FCVD process is preferably performed using carbon-free and silicon-nitrogen containing precursor to form the silicon-containing dielectric layer 104, wherein the carbon-free and silicon-nitrogen containing precursor comprises TSA, H₂N(SiH₃), HN(SiH₃)₂, N(SiH₃)₃, other types of silylamines or the arbitrary combination thereof. In addition, other processing gas, such as hydrogen gas (H₂), nitrogen gas (N₂), amnion (NH₃), hydrazine (N₂H₄), silane (SiH₄), helium (He), argon (Ar) or the arbitrary combinations thereof, may be added during the silicon-containing dielectric layer 104 deposition. In the present embodiment, TSA is applied serving as the carbon-free and silicon-nitrogen containing precursor for depositing the silicon-containing dielectric layer 104 on the surface 101a of the substrate 101 at a following conditions: a flow rate of 50 sccm, a processing temperature ranging from 150° C. to 500° C., and a pressure ranging from 50 torrs to 600 torrs.

After the formation of the silicon-containing dielectric layer 104, referring to the step S3 of FIG. 1, the silicon-containing dielectric layer 104 is subjected to a curing process 105 (as shown in FIG. 2C). In some embodiments of the present invention, the curing process 105 is performed on the silicon-containing dielectric layer 104 under a following conditions: a processing temperature ranging from 150° C. to 400° C. and a pressure ranging from 500 torrs to 700 torrs in an oxygen containing atmosphere comprising oxygen gas (O₂), ozone (O₃) or the combination thereof. In a preferred embodiment of the present invention, the curing process 105 is performed with in an oxygen containing atmosphere having a temperature of 150° C. and a pressure of 600 torrs, wherein the flow rate of O₂ is about 50 sccm, the flow rate of O₃ is about 27000 sccm. In addition, the oxygen containing atmosphere further comprises inert gas, such as N₂, He or the combination thereof having a flow rate about 3000 sccm.

Referring to the step S4 of FIG. 1, an in-situ wetting treatment 106 is then performed on the cured silicon-containing dielectric layer 104. The phrase of “in-situ” means that the curing process 105 and the wetting treatment 106 are performed in the same chamber with a single vacuum condition or are respectively carried out in different chambers of an identical apparatus without releasing vacuum condition. In other words, the processing pressure of the wetting treatment 106 is substantially equal to that of the curing process 105. In addition, in some embodiments of the present invention, the substrate temperatures both in the wetting treatment 106 and the curing process 105 are maintained substantially constant.

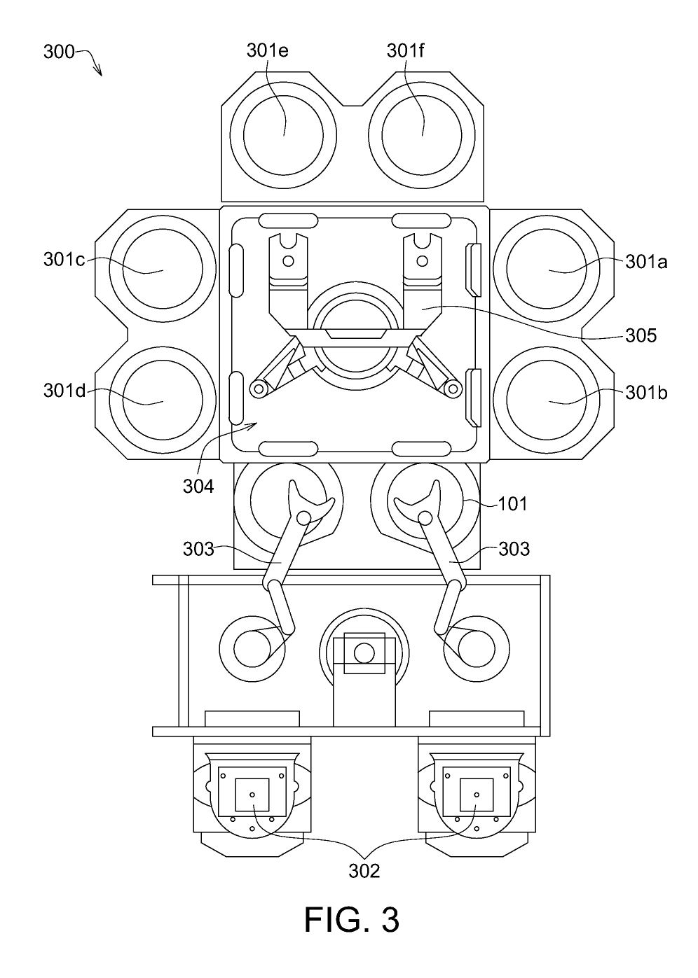

FIG. 3 is a top view of a processing apparatus 300 for forming the semiconductor device 10 in accordance with one embodiment of the present invention. The processing apparatus 300 comprises several chambers, such as the chambers 301a, 301b, 301c, 301e and 301f as shown in FIG. 3. The substrate 101 (wafer) having the silicon-containing dielectric layer 104 formed thereon is firstly taken from a front opening unified pod (FOUPs) 302 and then transferred into the pressure holding area 304 by the robotic arms 303. The robotic arms 305 carry on the task of procedure to transfer the substrate 101 (wafer) into one of the chambers 301a, 301b, 301c, 301e and 301f for performing a predetermined process, either a deposition process, an etching process, a cleaning process, a curing process, a wetting process or an thermal annealing process . . . etc. At the end of the predetermined process, the substrate 101 (wafer) is carried out of the chamber passing through the pressure holding area 304 and transformed into another chamber for performing the next process by the robotic arms 305. It should be appreciated that the processing apparatus 300 used to implement the present embodiment is just illustrative. It is not intended to be exhaustive or to be limited to the precise form disclosed. Other processing apparatus with various structures may be applied to implement the method or steps for fabricating a semiconductor device 10.

In some embodiments of the present invention, the wetting treatment 106 and the curing process 105 are performed in the same chamber, such as the chamber 301a, in which the processing pressure is remained about 600 torr, and the substrate temperature is remained about 150° C. In some other embodiments of the present invention, the wetting treatment 106 and the curing process 105 are respectively performed in different chambers of the same processing apparatus 300. For example, the curing process 105 and the wetting treatment 106 are respectively performed in the chambers 301a and 301b of the processing apparatus 300. While the cured substrate (wafer) is carried out from the chamber 301a and transformed passing through the pressure holding area 304, prior to being transformed into the chamber 301b for the next process, the pressures in the pressure holding area 304 and both of the chambers 301a and 301b are remained constant, preferably is remained about 600 torr. Thus the curing process 105 and the wetting treatment 106 can be performed without releasing vacuum condition.

The in-situ wetting treatment 106 comprises steps of making a water-containing agent directly in contact with the silicon-containing dielectric layer 104, wherein the water-containing agent comprising steam with a temperature ranging from about 100° C. to about 200° C. In the present embodiment, the in-situ wetting treatment 106 and the curing process 105 are performed in the same chamber, both the processing pressure and the subtract temperature applied to the in-situ wetting treatment 106 are identical to that applied to the curing process 105, preferably the pressure is remained about 600 torr and the substrate temperature is remained about 150° C. During the in-situ wetting treatment 106, the cured silicon-containing dielectric layer 104 is getting in contact with steam of 120° C. (see FIG. 2D) for a contacting interval ranging from about 2 minutes to about 10 minutes in a condition that the flow rates of other processing gases remain unchanged.

Subsequently, referring to the step S5 of FIG. 1, a thermal annealing process 107 is performed on the silicon-containing dielectric layer 104 treated by the wetting treatment, while forming the gap-filling dielectric layer 100 (see FIG. 2E). In consideration of the thermal budget for fabricating the semiconductor device 10, the thermal annealing process 107 may be a low temperature annealing process. In some embodiments of the present invention, the thermal annealing process 107 may be performed at a temperature ranging from about 150° C. to about 400° C. in an oxygen containing atmosphere. The oxygen containing atmosphere applied by the thermal annealing process 107 may comprise O₂, O₃, steam, hydrogen peroxide (H₂O₂) or the arbitrary combinations thereof. In the present embodiment, the thermal annealing process 107 is performed at a processing temperature about 300° C. in an O₃ atmosphere.

After the thermal annealing process 107 is carried out, a Fourier transform infrared (FTIR) spectrometer is used to determine structures and chemical compositions involved in the gap-filling dielectric layer 100 fabricated by the aforementioned method. In accordance with the FTIR absorption spectrum of the gap-filling dielectric layer 100, it reveals that there are several chemical bonds comprising Si—N bond, Si—O bond, S—OH bond and S—N bond involved in the gap-filling dielectric layer 100. Thus it can be concluded, but not limited, that the gap-filling dielectric layer 100 is made of silicon oxide (SiO₂) with silazane bonding thereon. In one embodiment of the present invention, the gap-filling dielectric layer 100 has a nitrogen atom density substantially less than 1×10²² atoms/cm³. In comparison with a prior art gap-filling dielectric layer, Si—N bonds involved in the gap-filling dielectric layer 100 is apparently less than that involved in the prior art gap-filling dielectric layer, and thus it can be indicated that the method for fabricating the gap-filling dielectric layer 100 has a greater efficiency in converting Si—N bonds to Si—O bonds than the method for fabricating the prior art gap-filling dielectric layer, and the texture of silicon oxide constituting the gap-filling dielectric layer 100 is more impact than the silicon oxide constituting the prior art gap-filling dielectric layer. In the present embodiment, the gap-filling dielectric layer 100 has a nitrogen atom density substantially less than 0.5×10²² atoms/cm³.

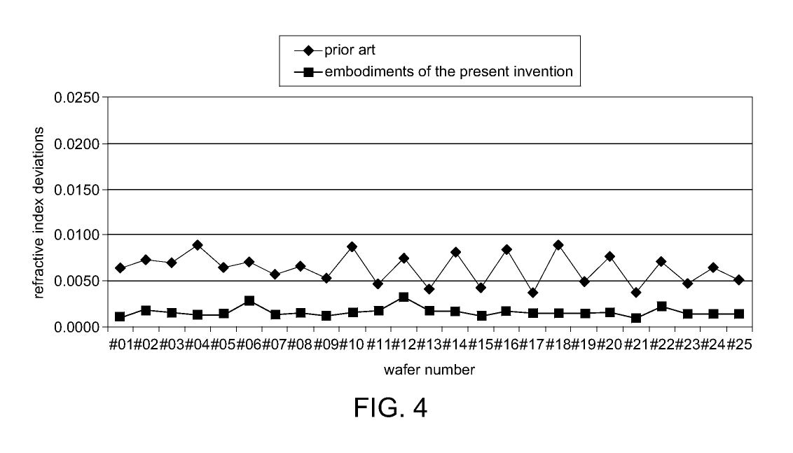

In addition, the geometries of the gap-filling dielectric layer 100 may be investigated by using an ellipsometer to measure the complex reflective index of the gap-filling dielectric layer 100. FIG. 4 is a statistic chart illustrating the reflective index deviations of different gap-filling dielectric layers that are measured by an ellipsometer in accordance with one embodiment of the present invention, where the X coordinate represents a serial number of investigated wafers; and the Y coordinate represents reflective index deviations of the investigated wafers measured at various locations on the surface thereof. By comparison with the investigation results of the different gap-filling dielectric layers, the reflective index deviations of the gap-filling dielectric layers 100 (see the curved line with diamond shaped dots) are apparently less than that of the prior art gap-filling dielectric layers (see the curved line with square shaped dots). It can be demonstrated that the gap-filling dielectric layers 100 provided by the embodiments of the present invention have more surface stability and uniformity than the prior art gap-filling dielectric layers.

Subsequently, referring to the step S6 of FIG. 1, a serial down-stream processes are performed on the gap-filling dielectric layers 100 to complete the formation of the semiconductor device 10. In some embodiments of the present invention, after several subsequent processes, such as an etching process, a chemical mechanical polish (CMP) process or the combination thereof, are carried out, the remaining portion of the gap-filling dielectric layers 100 may serve as a STI structure 108 of the semiconductor device 10. In some other embodiments of the present invention, the subsequent processes may comprise an interconnection process, and the remaining portion of the gap-filling dielectric layers 100 may serve as an interlay dielectric (ILD) 109 of the semiconductor device 10 allowing a plurality of vias 110 and metal wires 111 formed therein to connect the semiconductor elements (not shown) formed on/in the substrate 101.

In accordance with the aforementioned embodiments of the present invention, a substrate is firstly provided, and a silicon-containing dielectric layer is deposited on the substrate. The silicon-containing dielectric layer is then subjected to a curing process, an in-situ wetting treatment and an annealing process in sequence, whereby a gap-filling dielectric layer having a nitrogen atom density less than 1×10²² atoms/cm³ is formed on the substrate with a limited processing time and thermal budget. After a FTIR test and a reflective index deviations analysis are performed, it can be demonstrated that since the gap-filling dielectric layer has improved gap-filling ability and good dielectric properties, thus the problems encountered by the prior art gap-filling dielectric layer due to the shrink in feature sizes of semiconductor IC can be solved.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A gap-filling dielectric layer directly in contact with a silicon substrate, comprising: a nitrogen atom density substantially less than 1×10²² atoms/cm³.

2. The gap-filling dielectric layer according to claim 1, wherein the gap-filling dielectric layer is formed on the silicon substrate and filled in at least one trench formed in the silicon substrate.

3. The gap-filling dielectric layer according to claim 1, further comprises silicon oxide (SiO₂).

4. The gap-filling dielectric layer according to claim 1, comprises a shallow trench isolation (STI) structure, an interlayer dielectric (ILD) or the combination thereof.

5. A method for fabricating a gap-filling dielectric layer, comprising:
depositing a silicon-containing dielectric layer on a substrate;
performing a curing process on the silicon-containing dielectric layer;
performing an in-situ wetting treatment on the silicon-containing dielectric layer; and
performing an thermal annealing process on the silicon-containing dielectric layer.

6. The method according to claim 5, wherein the process for depositing the silicon-containing dielectric layer comprises trisilane (TSA) serving as a precursor.

7. The method according to claim 5, wherein the curing process is performed in an oxygen containing atmosphere with a curing temperature substantially ranging from 150° C. to 400° C.

8. The method according to claim 7, wherein the oxygen containing atmosphere comprises ozone (O₃).

9. The method according to claim 5, wherein the in-situ wetting treatment comprises steps of making a water-containing agent directly in contact with the silicon-containing dielectric layer.

10. The method according to claim 9, wherein the water-containing agent comprises steam with a temperature substantially ranging from 100° C. to 200° C.

11. The method according to claim 10, wherein the silicon-containing dielectric layer is getting in contact with the steam for a contacting interval substantially ranging from 2 minutes to 10 minutes.

12. The method according to claim 5, wherein the curing process and the in-situ wetting treatment are performed in the same chamber having a processing pressure about 600 torr.

13. The method according to claim 5, wherein the thermal annealing process has a temperature substantially ranging from 150° C. to 400° C.

14. The method according to claim 5, wherein the gap-filling dielectric layer has a nitrogen atom density substantially less than 1×10²² atoms/cm³ after the thermal annealing process is carried out.

15. A semiconductor device, comprising:
a silicon substrate; and
a gap-filling dielectric layer disposed on and directly in contact with the silicon substrate and having a nitrogen atom density substantially less than 1×10²² atoms/cm³.

16. The semiconductor device according to claim 15, wherein the silicon substrate comprises at least two trenches used to define at least one fin, and the gap-filling dielectric layer is filled in the trenches.

17. The semiconductor device according to claim 15, wherein the gap-filling dielectric layer comprises SiO₂.

18. The semiconductor device according to claim 15, wherein the gap-filling dielectric layer comprises a STI structure, an ILD or the combination thereof.

19. A method for fabricating a semiconductor device, comprising:
providing a substrate;
depositing a silicon-containing dielectric layer on the substrate;
performing a curing process on the silicon-containing dielectric layer;
performing an in-situ wetting treatment on the silicon-containing dielectric layer; and
performing an thermal annealing process on the silicon-containing dielectric layer.

20. The method according to claim 19, wherein the curing process and the in-situ wetting treatment are performed in the same chamber; and the in-situ wetting treatment comprises steps of making steam with a temperature substantially ranging from 100° C. to 200° C. directly in contact with the silicon-containing dielectric layer.
